(19) United States
(12) Patent Application Publication
(10) Pub. No.: US 2003/0102897 A1
(43) Pub. Date: Jun. 5, 2003

(54) Radiation resistant CMOS latch

(76) Inventors: David P. Hannum, Fort Collins, CO (US); Kevin D. Safford, Fort Collins, CO (US); Thomas J. Sullivan, Fort Collins, CO (US)

Correspondence Address: HEWLETT-PACKARD COMPANY, Intellectual Property Administration, P. O. Box 272400, Fort Collins, CO, 80527-2400, US

(21) Appl. No.: 10/005,088

(22) Filed: Dec. 4, 2001

(51) Int. Cl. H03K 3/037

(52) U.S. Cl. 327/205

(57) ABSTRACT

A CMOS latch with improved immunity to soft errors resulting from energetic particle strikes is disclosed. In one embodiment two Schmitt triggers are cross-coupled to hold a logic state. The significant hysteresis of the Schmitt triggers improves the resistance of the latch to induced soft errors. In a further embodiment, the Schmitt triggers operate by providing feedback from the Schmitt trigger output that changes the effective impedance of both the pullup and pulldown networks of the Schmitt trigger thereby creating significant hysteresis. In another embodiment, the Schmitt triggers operate by providing feedback from the Schmitt trigger output that changes the effective impedance of only one of either the pullup or pulldown network of the Schmitt trigger thereby creating significant hysteresis.

### FIELD OF THE INVENTION

This invention relates generally to CMOS integrated circuits and more particularly to a circuit for storing a digital state that has improved resistance to soft errors.

### BACKGROUND OF THE INVENTION

Natural background radiation, such as alpha particles and neutrons, can corrupt data stored in memory elements producing what is referred to as “soft errors.”When a particle strikes a diffusion layer of a field-effect transistor (FET), it generates electron-hole pairs. Electrons generated by this strike may then be collected at a node causing it to discharge thereby changing the state of the memory element or latch. Circuits constructed in advanced semiconductor technologies, such as those using gate widths less than 0.25 microns, are more susceptible to these soft errors. Accordingly, to ensure the reliability of integrated circuits, including microprocessors, there is a need for an improved latch circuit that has improved resistance to radiation induced soft errors.

### SUMMARY OF THE INVENTION

A CMOS latch with improved immunity to soft errors resulting from energetic particle strikes is provided. In one embodiment two Schmitt triggers are cross-coupled to hold a logic state. The significant hysteresis of the Schmitt triggers improves the resistance of the latch to induced soft errors. In a further embodiment, the Schmitt triggers operate by providing feedback from the Schmitt trigger output that changes the effective impedance of both the pullup and pulldown networks of the Schmitt trigger thereby creating significant hysteresis. In another embodiment, the Schmitt triggers operate by providing feedback from the Schmitt trigger output that changes the effective impedance of only one of either the pullup or pulldown network of the Schmitt trigger thereby creating significant hysteresis.

### BRIEF DESCRIPTION OF THE DRAWINGS

FIG. 1 is a schematic diagram illustrating one embodiment of the present invention.

FIG. 2 is a schematic diagram illustrating a second embodiment of the present invention.

FIG. 3 is a schematic diagram illustrating a third embodiment of the present invention.

### DETAILED DESCRIPTION OF THE PREFERRED EMBODIMENTS

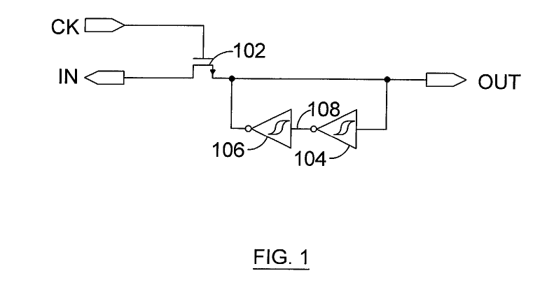

FIG. 1 is a schematic diagram illustrating one embodiment of the present invention. In FIG. 1, a pass-gate 102 comprised of an NFET (n-channel field-effect transistor) is connected between an input node, IN, and a keeper and output node, OUT. Pass-gate 102 is controlled by a signal CK. The input to Schmitt trigger 104 is also connected to keeper node OUT. The output of Schmitt trigger 104 is connected to feedback node 108. The input to Schmitt trigger 106 is connected to feedback node 108. The output of Schmitt trigger 106 is connected to keeper node OUT.

Pass-gate 102 either lets data flow through pass-gate 102 to setting the latch high or low, or pass-gate 102 blocks data from flowing allowing the feedback provided by Schmitt trigger 104 and 106 to hold keeper node OUT at either a high or low value. The Schmitt triggers 104 and 106 add hysteresis, when compared to conventional inverters, to the feedback path used to hold keeper node OUT at its value. This added hysteresis reduces the probability that a particle strike will change the value of the latch thereby making the latch of FIG. 1 more radiation resistant than a conventional CMOS latch.

The replacement of one or more of the feedforward, feedback, or both inverters by Schmitt triggers may be done on other latch configurations or topologies. By utilizing Schmitt triggers to add hysteresis in these other latch configurations or topologies, these other configurations or topologies may have their resistance to radiation improved. For example, some latch designs use the feedback node 108 as an input to an output inverter instead of taking the keeper node and using it as the output node as shown in FIG. 1. By replacing one or more of the feedforward or feedback inverters in this latch design, the radiation resistance of this latch design may be improved. It is contemplated that the radiation resistance of any latch design may be improved in a manner consistent with the invention by replacing one or more inverters with Schmitt trigger.

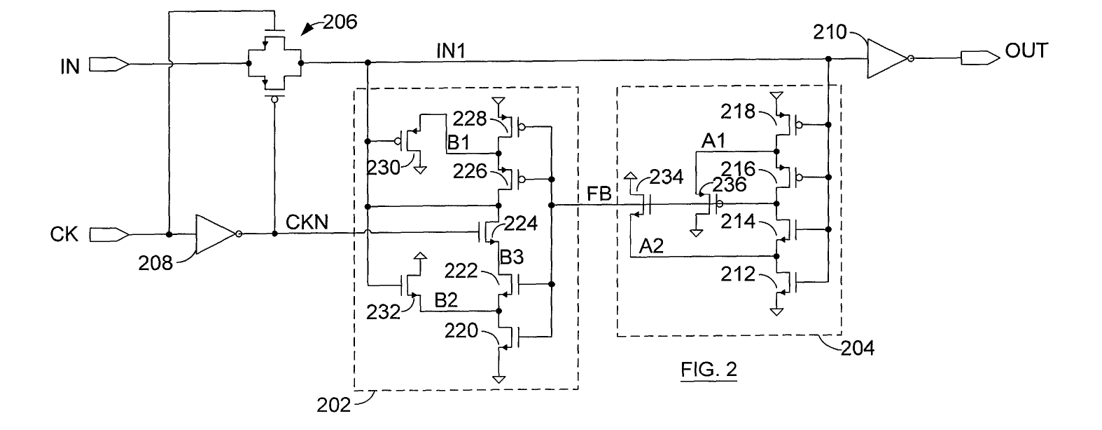

FIG. 2 is a schematic diagram illustrating a second embodiment of the present invention. In FIG. 2, a pass-gate 206 comprised of an NFET and a PFET (p-channel field-effect transistor) is connected between an input node, IN, and a keeper node IN1. Pass-gate 206 is controlled by a signal CK and a complement of CK, CKN that is generated from CK by inverter 208. The input to Schmitt trigger 204 is connected to keeper node IN1. The output of Schmitt trigger 204 is connected to feedback node FB. The input to Schmitt trigger 202 is connected to feedback node FB. The output of Schmitt trigger 202 is connected to keeper node IN1. Keeper node IN1 is also connected to the input of inverter 210. The output of inverter 210 is connected to output node OUT.

Schmitt trigger 204 is comprised of NFETs 212, 214, and 234 and PFETs 216, 218, and 236. The gates of FETs 212, 214, 216, and 218 are all connected to the input of Schmitt trigger 204—keeper node IN1. The source of PFET 218 is connected to a positive supply voltage. The drain of PFET 218 is connected to node A1. Node A1 is also connected to the sourced of PFETs 216 and 236. The drain of PFET 216 is connected to the output of Schmitt trigger 204—feedback node FB. The drain of PFET 236 is connected to a negative supply voltage. The gate of PFET 236, the gate of NFET 234, and the drain of NFET 214 are also connected to node FB. The source of NFET 214 is connected to node A2. The source of NFET 234 and the drain of NFET 212 are also connected to node A2. The source of NFET 212 is connected to a negative supply voltage. The drain of NFET 234 is connected to a positive supply voltage.

Schmitt trigger 202 is comprised of NFETs 220, 222, 224 and 232 and PFETs 226, 228 and 230. The gates of FETs 220, 222, 224, 226, and 228 are connected to the input of Schmitt trigger 202—feedback node FB. The source of PFET 228 is connected to a positive supply voltage. The drain of PFET 228 is connected to node B1. Node B1 is also connected to the sourced of PFETs 226 and 230. The drain of PFET 226 is connected to the output of Schmitt trigger 202—keeper node IN1. The drain of PFET 230 is connected to a negative supply voltage. The gate of PFET 230, the gate of NFET 232, and the drain of NFET 224 are also connected to node IN1. The source of NFET 224 is connected to node B3. The gate of NFET 224 is connected to node CKN. The drain of NFET 222 is connected to node B3. The source of NFET 222 is connected to node B2. The source of NFET 232 and the drain of NFET 220 are also connected to node B2. The source of NFET 220 is connected to a negative supply voltage. The drain of NFET 232 is connected to a positive supply voltage.

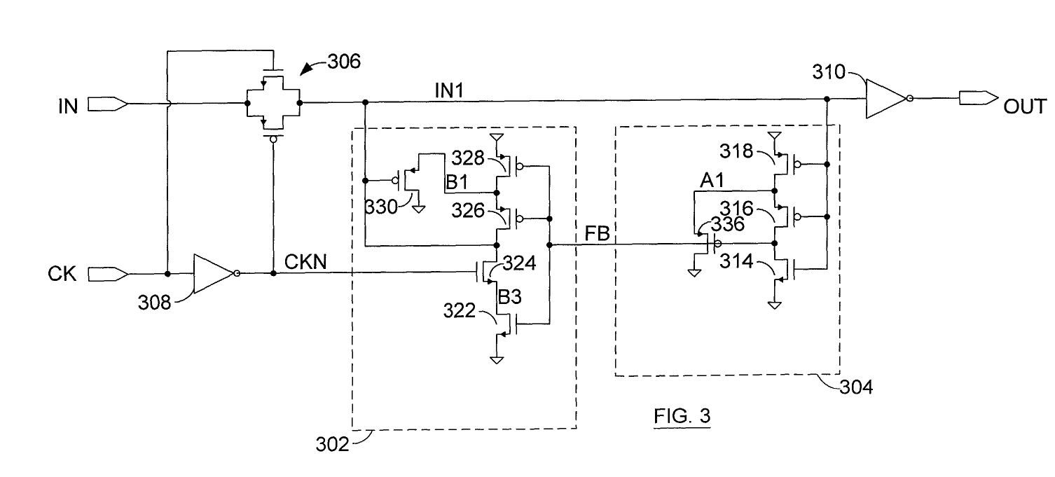

Pass-gate 206 either lets data flow through pass-gate 206 to setting the latch high or low, or pass-gate 206 blocks data from flowing allowing the feedback provided by Schmitt trigger 204 and 202 to hold keeper node IN1 at either a high or low value. The Schmitt triggers 204 and 202 add hysteresis, when compared to conventional inverters, to the feedback path used to hold keeper node IN1 at its value. This added hysteresis reduces the probability that a particle strike will change the value of the latch thereby making the latch of FIG. 2 more radiation resistant than a conventional CMOS latch. In the embodiment shown in FIG. 2, NFET 234 and PFET 236 are used to add hysteresis to Schmitt trigger 204. Likewise, NFET 232 and PFET 230 add hysteresis to Schmitt trigger 202. NFETs 232 and 234 operate to provide feedback from the output of Schmitt triggers 202 and 204, respectively, that changes the effective impedance of the pulldown networks in Schmitt triggers 202 and 204, respectively. Likewise, PFETs 230 and 236 operate to provide feedback from the output of Schmitt triggers 202 and 204, respectively, that changes the effective impedance of the pullup networks in Schmitt triggers 202 and 204, respectively. In another embodiment, one of more of NFETs 232 and 234 and/or PFETs 236 and 230 may be removed. These embodiments should cost less (because they may be fabricated using less area) and have shorter setup and hold times than the embodiment shown in FIG. 2. An example embodiment with NFETs 232 and 234 removed is shown in FIG. 3. The embodiment shown in FIG. 3 changes only the resistance ratio of the pullup network. However, a Schmitt trigger that only changes the resistance ratio of the pulldown network may also be constructed.

FIG. 3 is a schematic diagram illustrating a third embodiment of the present invention. In FIG. 3, a pass-gate 306 comprised of an NFET and a PFET is connected between an input node, IN, and a keeper node IN1. Pass-gate 306 is controlled by a signal CK and a complement of CK, CKN that is generated from CK by inverter 308. The input to Schmitt trigger 304 is connected to keeper node IN1. The output of Schmitt trigger 304 is connected to feedback node FB. The input to Schmitt trigger 302 is connected to feedback node FB. The output of Schmitt trigger 302 is connected to keeper node IN1. Keeper node IN1 is also connected to the input of inverter 310. The output of inverter 310 is connected to output node OUT.

Schmitt trigger 304 is comprised of NFET 314 and PFETs 316, 318, and 336. The gates of FETs 314, 316, and 318 are all connected to the input of Schmitt trigger 304—keeper node IN1. The source of PFET 318 is connected to a positive supply voltage. The drain of PFET 318 is connected to node A1. Node A1 is also connected to the source of PFETs 316 and 336. The drain of PFET 316 is connected to the output of Schmitt trigger 304—feedback node FB. The drain of PFET 336 is connected to a negative supply voltage. The gate of PFET 336 and the drain of NFET 314 are connected to node FB. The source of NFET 314 is connected to node a negative supply voltage.

Schmitt trigger 202 is comprised of NFETs 322, and 324 and PFETs 326, 328 and 330. The gates of FETs 322, 326, and 328 are connected to the input of Schmitt trigger 302—feedback node FB. The source of PFET 328 is connected to a positive supply voltage. The drain of PFET 328 is connected to node B1. Node B1 is also connected to the source of PFETs 326 and 330. The drain of PFET 326 is connected to the output of Schmitt trigger 302—keeper node IN1. The drain of PFET 330 is connected to a negative supply voltage. The gate of PFET 330 and the drain of NFET 324 are connected to node IN1. The source of NFET 324 is connected to node B3. The gate of NFET 324 is connected to node CKN. The drain of NFET 322 is connected to node B3. The source of NFET 322 is connected to a negative supply voltage.

Pass-gate 306 either lets data flow through pass-gate 306 to setting the latch high or low, or pass-gate 306 blocks data from flowing allowing the feedback provided by Schmitt trigger 304 and 302 to hold keeper node IN1 at either a high or low value. PFETs 330 and 336 operate to provide feedback from the output of Schmitt triggers 302 and 304, respectively, that changes the effective impedance of the pullup networks in Schmitt triggers 302 and 304, respectively. The Schmitt triggers 304 and 302 add hysteresis, when compared to conventional inverters, to the feedback path used to hold keeper node IN1 at its value. This added hysteresis reduces the probability that a particle strike will change the value of the latch thereby making the latch of FIG. 3 more radiation resistant than a conventional CMOS latch but because it has fewer transistors it may be constructed in less area than the latch shown in FIG. 2. This reduces cost. Also, the embodiments that only change the effective impedance of one of either the pullup or pulldown networks tend to have shorter setup and hold times.

What is claimed is:

1. A latch, comprising:
a first Schmitt trigger having a first output coupled to a feedback node and a first input coupled to a keeper node;
a second Schmitt trigger having a second output coupled to said keeper node and a second input coupled to said feedback node wherein said first and second Schmitt triggers exhibit significant hysteresis thereby making said latch resistant to particle strikes.

2. A latch, comprising:
a first and second Schmitt trigger each comprised of a first pullup path and first pulldown path and an output of each Schmitt trigger provides feedback to change the impedance of said first pullup and said first pulldown path thereby causing said Schmitt triggers to exhibit significant hysteresis, and wherein said output of said second Schmitt trigger is coupled to a first input of said first Schmitt trigger and said output of said first Schmitt trigger is coupled to a second input of said second Schmitt trigger wherein said significant hysteresis thereby makes said latch resistant to particle strikes.

3. A latch, comprising:
a first and second Schmitt trigger each comprised of a first pullup path and first pulldown path and an output of each Schmitt trigger provides feedback to change the impedance of one of said first pullup and said first pulldown path thereby causing said Schmitt triggers to exhibit significant hysteresis, and wherein said output of said second Schmitt trigger is coupled to a first input of said first Schmitt trigger and said output of said first Schmitt trigger is coupled to a second input of said second Schmitt trigger wherein said significant hysteresis thereby makes said latch resistant to particle strikes.

4. A latch, comprising:
a pass-gate blocking and passing an input signal to a keeper node;
a first and second Schmitt trigger cross-coupled to store a logic state on said keeper node when said pass-gate is blocking said input signal wherein said first and second Schmitt trigger exhibit enough hysteresis to make said latch resistant to particle strikes.

5. The latch of claim 4 wherein said first and second Schmitt triggers comprise:
a pullup path capable of sourcing a first current to an output node;
a feedback path that alters the magnitude of said first current based upon the voltage on said output node thereby causing said Schmitt triggers to exhibit said enough hysteresis to make said latch resistant to particle strikes.

6. The latch of claim 4 wherein said first and second Schmitt triggers comprise:
a pulldown path capable of sinking a first current from an output node;
a feedback path that alters the magnitude of said first current based upon the voltage on said output node thereby causing said Schmitt triggers to exhibit said enough hysteresis to make said latch resistant to particle strikes.

7. The latch of claim 4 wherein said first and second Schmitt triggers comprise:
a pullup path capable of sourcing a first current to an output node;
a pulldown path capable of sinking a first current from said output node;
a first feedback path that alters the magnitude of said first current based upon the voltage on said output node;
a second feedback path that alters the magnitude of said second current based upon the voltage on said output node; and,
wherein said first and second feeback paths in combination thereby cause said Schmitt triggers to exhibit said enough hysteresis to make said latch resistant to particle strikes.

8. A method of making a latch resistant to particle strikes, comprising:
replacing a feedback and a feedforward inverter with at least one Schmitt trigger causing said latch to exhibit increased hysteresis thereby making said latch resistant to particle strikes.

9. A method of making a latch resistant to particle strikes, comprising:
fabricating a latch comprised of Schmitt triggers instead of inverters in the feedforward and feedback path.

10. A method of resisting errors caused by particle strikes, comprising:
holding data with a latch comprised of Schmitt triggers in a feedforward path and a feedback path.

11. A method of resisting errors caused by particle strikes, comprising:
increasing the hysteresis associated with circuits performing an inverting function in a feedforward path and a feedback path of a latch.
